(19) United States
(12) Patent Application Publication
(10) Pub. No.: US 2009/0050879 A1
(43) Pub. Date: Feb. 26, 2009

(54) ORGANIC THIN FILM TRANSISTOR AND ACTIVE MATRIX DISPLAY

(76) Inventors: Takumi Yamaga, Kanagawa (JP); Hidenori Tomono, Kanagawa (JP); Ikue Kawashima, Kanagawa (JP)

Correspondence Address: COOPER & DUNHAM, LLP, 30 Rockefeller Plaza, 20th Floor, NEW YORK, NY, 10112, US

(21) Appl. No.: 11/914,032

(22) PCT Filed: May 9, 2006
(86) PCT No.: PCT/JP2006/309626

§ 371 Date: Nov. 9, 2007

(30) Foreign Application Priority Data
May 18, 2005 (JP) 2005-146047
Apr. 4, 2006 (JP) 2006-103671

(51) Int. Cl. H01L 51/05

(52) U.S. Cl. 257/40; 257/E51.006

(57) ABSTRACT

An organic thin film transistor is disclosed. The organic thin film transistor includes a substrate, a gate electrode , a gate insulating film , a source electrode on the gate insulating film, a drain electrode on the gate insulating film at an interval with the source electrode, and an organic semiconductor layer. The gate insulating film includes an electrode formation region having surface energy modified by energy deposition, one or more corners of the electrode formation region has an obtuse-angled shape, and the source electrode and/or the drain electrode is formed in the electrode formation region so as to have substantially the same corner shape as the electrode formation region having the obtuse-angled shaped corners.

### TECHNICAL FIELD

The present invention relates to a thin film transistor having an organic semiconductor layer, and an active matrix display using the organic thin film transistor.

### BACKGROUND ART

Extensive study has been made of a thin film transistor using organic semiconductor materials.

Employing organic semiconductor materials in transistors brings the following advantages. 1). It is possible to obtain a large variety of material composition, and obtain high flexibility of the fabricating methods and of the product forms. 2). It is easy to obtain a large area of the transistor. 3). It is possible to simplify the fabricating process with a simplified layer structure. 4). It is possible to reduce the cost of the fabricating apparatus.

Since it is possible to easily form the organic thin film or a circuit by any one of the methods of printing, spin-coating, or dipping, or others, it is possible to fabricate the organic thin film transistor at much lower cost than a semiconductor device based on silicon of the related art.

When integrating organic thin film transistors, it is required to form a pattern as explained below. If the organic thin film transistors are integrated without patterning, when the transistors are in operation, the OFF currents of the transistors increase, and power consumption rises. This may cause cross-talk when using the transistors to display pixels. In the semiconductor device based on silicon of the related technology, this pattern is formed using photolithography process.

As for the organic thin film transistors, inkjet printing is a promising method for the patterning. For example, Japanese Laid Open Patent Application No. 2004-297011 (below, referred to as “reference 1”) discloses a method of fabricating an organic thin film transistor by providing charges so as to pattern with the Coulomb force of the charges, thereby resulting in high accuracy and small fluctuations of performance, by patterning with dents, or by patterning with laser exposure.

In addition, for example, Japanese Laid Open Patent Application No. 2004-141856 (below, referred to as “reference 2”) discloses a method of patterning a source electrode and a drain electrode involving forming an indent and discharging electrode materials thereon by a recording head of an inkjet device.

When fabricating a pattern of an organic semiconductor layer, the following method may be utilized, which method includes the steps of applying photo resist, exposing and developing a desired pattern, forming a resist pattern, performing etching with the resist pattern as a mask, and removing the resist to form a pattern.

However, when using polymer materials as the organic semiconductor material, if the photo resist is applied on a polymer active layer to form a pattern, the performance of the transistor may be degraded.

In addition, since the photo resist is obtained by dissolving a novolac resin, which has a naphthoquinonediazide as a photosensitive group, in an organic solvent such as xylene and cellosolve solvents, the polymer may be dissolved in the organic solvent included in the photo resist.

When using crystalline materials like pentacene as the organic semiconductor material, more or less performance degradation is confirmed after the photolithography process.

When removing the resist after the photolithography process, the solutions used for removal, such as ethylene glycol monobutyl ether or monoethanolamine, may cause damage, and rinsing with purified water after the removal step with the solutions may also cause damage.

Japanese Laid Open Patent Application No. 2003-536260 (below, referred to as “reference 3”) discloses a method of patterning by vacuum deposition, using a shadow mask, of crystalline materials such as pentacene, which is an organic semiconductor material. However, in the method disclosed in reference 3, the size of the pattern is limited by the shadow mask, and it is difficult to form a film of a large area. In addition, the shadow mask has limited product cycle; as a result, it is difficult to reduce the manufacturing cost.

Japanese Laid Open Patent Application No. 2002-540591 (below, referred to as “reference 4”) also discloses a method in this field.

When using a polymer material soluble in an organic solvents it is possible to pattern by inkjet printing. However, considering the landing accuracy of ink droplets, it is difficult to pattern with features less than 50 μm, and it is difficult to realize fine photolithography.

Returning to the issue of fabricating the organic thin film transistor by inkjet printing, because it is possible to directly perform patterning on a substrate by inkjet printing, the usability of the materials is improved. Thus, when applying the inkjet printing to pattern of the organic semiconductor layer, it is possible to simplify the fabrication process, improve the yield, and reduce the cost.

However, in the inkjet printing, it is difficult to reduce the size of the discharged ink droplet. Thus in order to further improve the resolution, particularly concerning fabrication of the source electrode and the drain electrode, it is necessary to change the performance of the substrate surface where the ink droplet lands.

Between the source electrode and the drain electrode, in order to obtain a desired current, a pattern a few μm is required. However, when forming a pattern a few μm on the substrate, the electrode material may leak out from electrode pattern region , and this results in failure of patterning , and may cause a short circuit.

Although the pattern can be formed by reducing the size of the discharged ink droplets, this also suffers-from some limitations. Further, if considering landing accuracy of the ink droplet in the inkjet printing, namely, the accuracy of discharging the ink droplet, or the accuracy of feeding of the stage where the substrate is placed, it is very difficult to pattern with high accuracy. Of course, even when the material properties of the discharged ink droplet (for example, viscosity, surface tension, dryness) change slightly, these changes may cause discharge bending or tails (ligaments). Due to this, the electrode patterns cannot be formed as desired, and electrical short circuits or disconnection may occur.

### DISCLOSURE OF THE INVENTION

The present invention may solve one or more of the problems of the related art.

A preferred embodiment of the present invention may provide an organic thin film transistor having high performance.

According to a first aspect of the present invention, there is provided an organic thin film transistor comprising a substrate; a gate electrode; a gate insulating film ; a source electrode on the gate insulating film; a drain electrode on the gate insulating film at an interval with the source electrode; and an organic semiconductor layer , wherein the gate insulating film includes an electrode formation region having surface energy modified by energy deposition, one or more corners of the electrode formation region have an obtuse-angled shaper and the source electrode and/or the drain electrode is formed in the electrode formation region so as to have substantially the same shape as the electrode formation region having the obtuse-angled shaped corners.

According to a second aspect of the present invention, there is provided an organic thin film transistor, comprising a substrate; a gate; a gate insulating film; a source electrode on the gate insulating film; a drain electrode on the gate insulating film at an interval with the source electrode; and an organic semiconductor layer , wherein the gate insulating film includes an electrode formation region having surface energy modified by energy deposition, one or more corners of the electrode formation region have a round shape, and the source electrode and/or the drain electrode is formed in the electrode formation region so as to have substantially the same shape as the electrode formation region having the round corners.

According to a third aspect of the present invention, there is provided an organic thin film transistor, comprising a substrate; a gate electrode; a gate insulating film; a source electrode on the gate insulating film; a drain electrode on the gate insulating film at an interval with the source electrode; and an organic semiconductor layer , wherein the source electrode and the drain electrode are formed on the gate insulating film having surface energy modified by energy deposition, and the source electrode and/or the drain electrode has at least one projecting portion.

According to a fourth aspect of the present invention, there is provided an active matrix display device, comprising a plurality of pixels, each pixel having an organic thin film transistor as an active device, wherein the organic thin film transistor includes a substrate; a gate electrode; a gate insulating film; a source electrode on the gate insulating film; a drain electrode on the gate insulating film at an interval with the source electrode; and an organic semiconductor layer wherein the gate insulating film includes an electrode formation region having surface energy modified by energy deposition, one or more corners of the electrode formation region have an obtuse-angled shape, and the source electrode and/or the drain electrode is formed in the electrode formation region so as to have substantially the same shape as the obtuse-angled shape of the corners of the electrode formation region.

According to the present invention, it is possible to provide an organic thin film transistor fabricated by using a fine source/drain electrode pattern. When fabricating an organic thin film transistor backplane of an active matrix display device, it is possible to directly draw a precise pattern on the substrate by inkjet printing, and it is possible to simplify the fabrication process, improve the yield, and reduce the cost.

In addition, since the organic insulating film includes polyimide, the surface energy can be modified by ultraviolet ray exposure; thus it is possible to directly draw a precise electrode pattern on the substrate by inkjet printing or dispenser printing.

Preferably, the metal ink is prepared by dispersing fine metal particles, and preferably, the fine metal particles include Au, Ag, Cu, Pt, Pd, Ni, Ir, Rh, Co, Fe, Mn, Cr, Zn, Mo, W, Ru, In, or Sn, or any combination of them. Especially Au, Ag, Cu, and Ni are preferable because they are superior in the electrical resistance, the thermal conductivity, and the corrosion resistance.

The metal ink is fabricated by dispersing fine metal particles having an average particle diameter from a few nm to a few tens nm in a solution uniformly.

It is known that the fine metal particles are sintered at a very low temperature. This is because along with a smaller and smaller particle diameter, the influence of highly active surface atoms prevails. When forming films by inkjet printing using the metal ink and performing sintering, it is possible to directly draw a precise electrode pattern on the substrate.

However, in inkjet printing, it is necessary to consider the material properties of the metal ink. For example, if the surface tension of the metal ink is not appropriate, probably the metal ink cannot be discharged or cannot be discharged correctly. In addition, if the viscosity of the metal ink is not appropriate, the metal ink droplet cannot have a spherical shape, and tails (ligaments) may become long.

Therefore, preferably, the metal ink has the following material properties. Specifically, the surface tension is about 30 mN/m and the viscosity is from about 2 mPa·s to about 13 mPa , s, more preferably, from about 7 mPa·s to about 10 mPa·s. Further, preferably, the metal ink has dryness such that the solvent is not volatilized during the discharge to make the fine metal particles into blocks.

In addition, it is preferable that the gate electrode, the source electrode, and the drain electrode be formed from a conductive polymer material. The conductive polymer material may include polythiophen, polyaniline, polypyrrole, poly-para-phenylene, polyacetylene, or a polymer with these materials doped. Particularly, the complex of polyethylenedioxythiophene (PEDOT) and polystyrene sulfonate (PSS) (the complex is denoted to be “PEDOT/PSS”) is preferable because of its good electrical conductivity, stability, and thermal resistance.

Although the conductive polymer material is not as good as the metal ink in electrical characteristics and stability, the electrical characteristics and stability of the conductive polymer material can be improved by the polymerization grade and the structure thereof. Further, because sintering is not necessary for the conductive polymer material, it is possible to reduce the fabrication temperature when using the conductive polymer material.

Further, according to an embodiment of the present invention, by combining an active matrix backplane having the organic thin film transistors and pixel devices , it is possible to fabricate a display panel at low cost and of superior flexibility.

These and other objects, features, and advantages of the present invention will become more apparent from the following detailed description of preferred embodiments given with reference to the accompanying drawings.

### BRIEF DESCRIPTION OF THE DRAWINGS

FIG. 1 is a plan view illustrating a conventional electrode pattern;

FIG. 2 is a plan view illustrating an electrode pattern having corners of modified shapes according to a first embodiment of the present invention;

FIG. 3 is a plan view illustrating an electrode pattern according to a second embodiment of the present invention;

FIG. 4 shows a relationship between the landing accuracy of the ink droplets and the resolution between the source electrode and the drain electrode;

FIG. 5 is a schematic cross sectional view illustrating a structure of the transistor according to the first embodiment;

FIG. 6 shows static characteristics of the transistor of the first example, in which the electrodes are formed from Ag ink and have obtuse-angled corners;

FIG. 7 shows static characteristics of the transistor of the first embodiment, in which the electrodes are formed from PEDOT/PSS and have obtuse-angled corners; and

FIG. 8 shows static characteristics of the transistor of the second embodiment, in which the electrodes have projecting portions.

### BEST MODE FOR CARRYING OUT THE INVENTION

Below, preferred embodiments of the present invention are explained with reference to the accompanying drawings.

### First Embodiment

In the inkjet printing, since it is difficult to reduce the size of the discharged ink droplet, it is necessary to modify the characteristics of the surface of substrate where the ink lands in order to further improve the resolution.

For example, a fine pattern can be formed in the following way. First, water-soluble ink is deposited by inkjet printing on a surface of a substrate including a portion having high surface energy and a portion having low surface energy; then, an ink film is formed only in the portion having the high surface energy. In this way, a fine pattern can be formed.

As described above, when forming the source and drain electrode patterns less than a few μm on the substrate , the electrode material may leak out from the source and drain electrode patterns, resulting in failure of pattern formation and a short circuit.

In order to form the electrode pattern as desired with the discharged electrode materials without occurrence of the short circuit, the electrode pattern can be formed by inkjet printing utilizing the difference of the surface energy of the substrate, and the shape of the electrode can be appropriately modified.

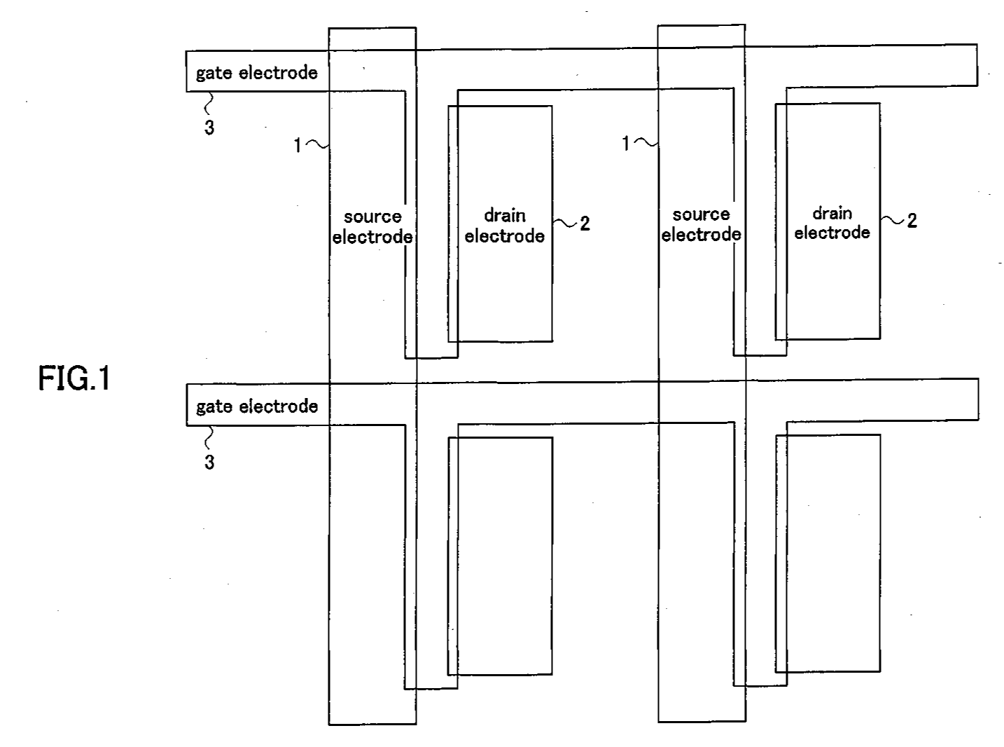

FIG. 1 is a plan view illustrating a conventional electrode pattern.

The electrode pattern shown in FIG. 1 includes source electrodes 1, drain electrodes 2, and gate electrodes 3.

In FIG. 1, the source electrodes 1 and the drain electrodes 2 have rectangular shapes with right angle corners. When the intervals between the source electrode patterns and the drain electrode patterns are a few μm, the electrode materials may contact each other, causing an electrical short circuit, and in turn causing failure of transistor fabrication. There are two possible reasons for this problem. First, due to incorrect ink discharge, fluctuation occurs and the electrode materials are discharged to other places than the electrode formation region. Second, the electrode materials leak out from the object electrode patterns.

The pattern can be formed by reducing the size of the discharged ink droplets with an inkjet device, but the effect is limited. In addition, it is difficult to completely prevent changes of the material properties of the electrode materials, and it is difficult to completely prevent incorrect ink discharge.

Further, the nozzles of the recording head of the inkjet device have small fluctuations, and the electrode materials are discharged to positions deviating from the intended position. In addition, discharge bending occurs due to the changes of the material properties of the electrode materials. These deviated electrode materials may cause an electrical short circuit.

When the source electrodes 1 and the drain electrodes 2 have rectangular shapes of right angle corners, the excessive electrode materials discharged to the electrode patterns tend to gather at the right angle corners where the surface energy is high. For this reason, the electrode material gathered at the right angle corners have contact angles greater than 20 degrees relative to the surface of the substrate, and thus, the electrode materials leak out from the corners. When the intervals between the source electrode patterns and the drain electrode patterns are a few μm, the electrode materials may come into contact with each other, causing an electrical short circuit.

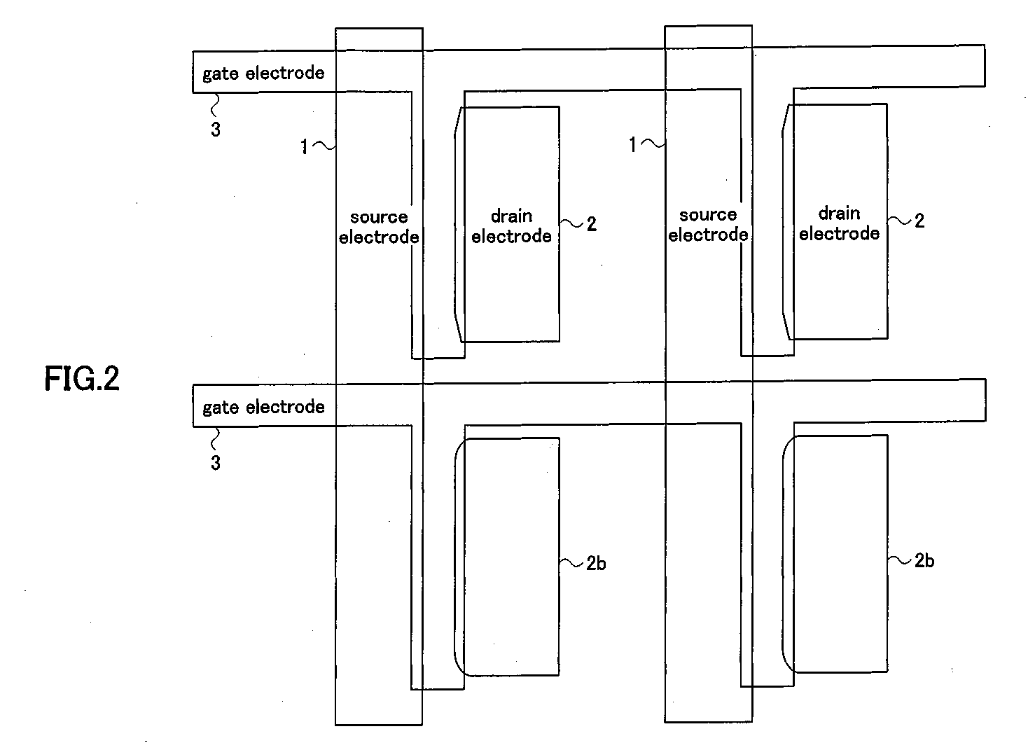

FIG. 2 is a plan view illustrating an electrode pattern having corners of modified shapes according to a first embodiment of the present invention.

In order to prevent the leaked electrode materials from coming into contact with each other, as shown in the upper portion in FIG. 2, corners of the ends of the electrodes along the channel region are made into obtuse-angled shapes.

Certainly, as shown in the lower portion in FIG. 2, corners of the ends of the electrodes along the channel region can be made into round shapes (2b).

When ultraviolet rays are irradiated by using a photo mask, the obtuse-angled shaped portion of the electrode pattern has high surface energy and other portions have low surface energy.

With such shaped corners because of the surface energy difference between the high surface energy and the low surface energy, the electrode materials are formed only in the portion having the high surface energy. In other words, for the ink droplets (electrode material) landing in the boundary region between the high surface energy area and the low surface energy area, the ink droplets landing in the area having low surface energy is drawn to flow to the area having high surface energy. The electrode material formed on the electrode pattern flows more or less because of the obtuse-angled effect, and does not gather at the corners; and for the contact angles less than 20 degrees relative to the surface of the substrate, the electrode material does not leak out from the electrode pattern. As a result, it is possible to prevent the embossment of electrode material at the corner of electrode pattern, and improve the flatness of the pattern.

Due to this, it is possible to fabricate a transistor with intervals between the patterns being a few μm as desired, and improve reliability and yield of the next step.

FIG. 4 shows a relationship between the landing accuracy of the ink droplets and the resolution between the source and the drain electrodes.

When forming the electrode patterns with a usual inkjet device (indicated by triangles in FIG. 4), the improvement of the resolution depends on the landing accuracy of the ink droplets. However, when forming the electrode patterns with an inkjet printing device utilizing the difference of the surface energy (indicated by squares in FIG. 4), because incorrect ink discharge is preventable, the resolution is improved significantly. In addition, when electrodes having obtuse-angled corners are adopted (indicated by diamonds in FIG. 4), it is possible to prevent the leakage of electrode material after landing of the ink droplets, and this further improves the resolution. In the inkjet printing, for example, when the ink droplet is 8 pl(pico liter), even though the landing accuracy is 25 μm, by utilizing the difference of the surface energy, and further by adopting electrodes having obtuse-angled shaped corners, it is possible to achieve good yield from patterning a 5 μm channel.

Below, a method of fabricating a transistor of the present embodiment is described.

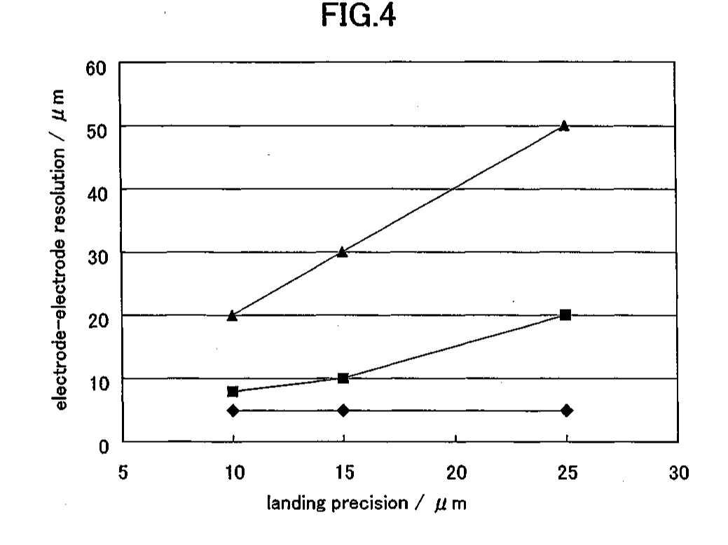

FIG. 5 is a schematic cross-sectional view illustrating a structure of the transistor according to the present embodiment.

As shown in FIG. 5, on a glass substrate 5, for example, the gate electrode 3 is formed from Al or Cr by vacuum deposition, and polyimide is applied on the gate electrode 3 to form an insulating film 6.

Then ultraviolet rays are irradiated on the polyimide insulating film 6 by using a photo mask to form electrode patterns, which patterns are used for subsequently forming the source electrode 1 and the drain electrode 2.

On the thus formed patterns, for example, the source electrode 1 and the drain electrode 2 are formed by printing a PEDOT/PSS solution (PEDOT: polyethylenedioxythiophene, PSS: polystyrene sulfonate) by means of inkjet printing or dispenser printing, and then an organic semiconductor material is applied by spin-coating to form an organic semiconductor layer 4.

In doing so, a transistor as shown in FIG. 5 is formed, which transistor has a stacked structure including the glass substrate 5, the aluminum gate electrode 3, the polyimide insulating film 6, the source electrode 1 and the drain electrode 2 formed from PEDOT/PSS, and the organic semiconductor layer 4.

Below, the characteristics of the thus fabricated transistor are described.

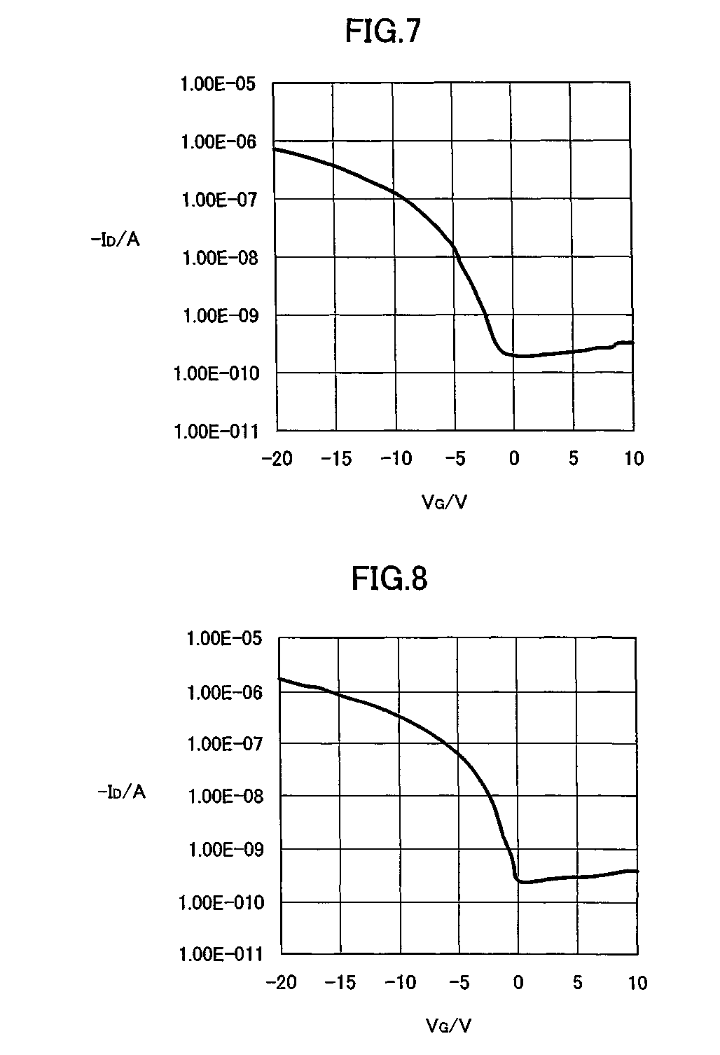

FIG. 7 shows static characteristics of the transistor of the present embodiment, in which the electrodes are formed from PEDOT/PSS and have obtuse-angled corners. In FIG. 7, the abscissa represents a gate voltage Vg, and the ordinate represents a drain current-Id.

The Vg-Id characteristics of the transistor as shown in FIG. 7 are described below.

In the ON state (namely, operational state), the drain current-Id=0.8×10⁻⁶ A. (Specifically, in the ON state, Vg=−20 V.)

In the OFF state (namely, non-operational state), the drain current-Id=2.5×10⁻²⁰ A. (In the OFF state, Vg=0 V.)

Thus, the ratio of the drain current-Id when Vg=-20 V over the drain current-Id when Vg=0 V (below, referred to as “ON/OFF ratio”) is 3.5×10³.

This implies that an electrical short circuit does not occur between the source electrode and the drain electrode, and good transistor characteristics are obtained.

The ON state current of a field effect transistor (that is, the operational state current) is expressed as below.

Id=W/2L×μ×Ci×(Vg−Vth)²

Where Id is the drain current (ON state current), W represents a channel width, L represents a channel length, μ represents mobility, Ci represents a static capacitance of the gate insulating film, Vg represents the gate voltage, and Vth represents a threshold voltage.

In order to increase the drain current (ON state current), it is sufficient to increase the channel width W and reduce the channel length L. The channel width W depends on the electrode length.

### Second Embodiment

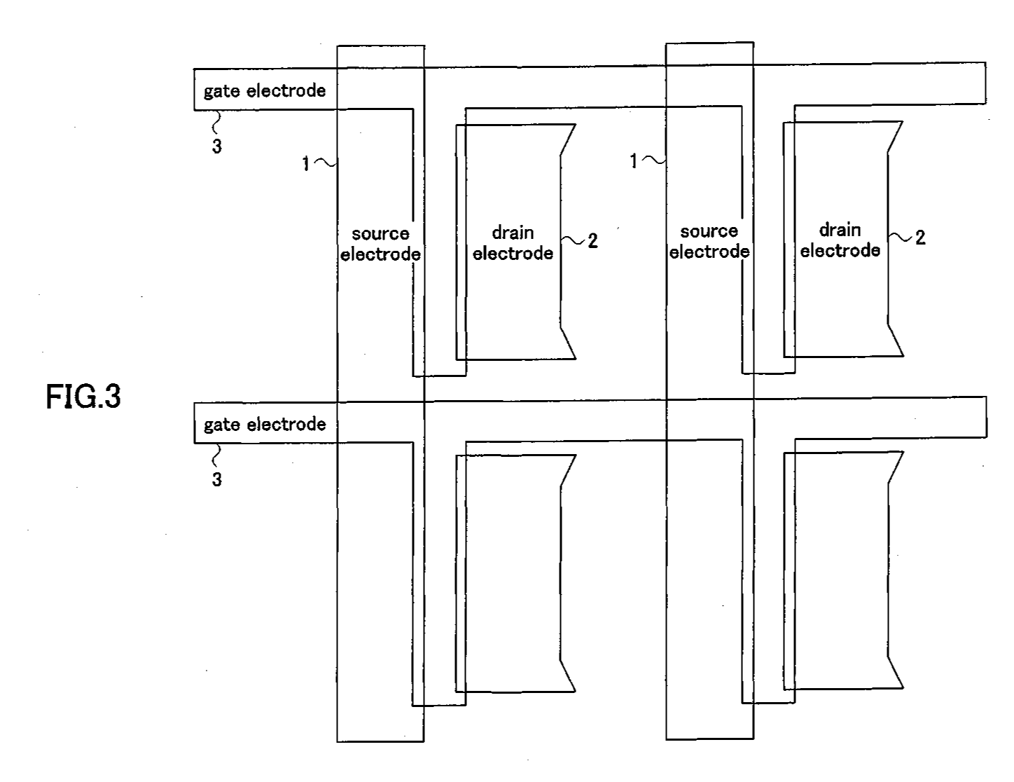

FIG. 3 is a plan view illustrating an electrode pattern according to a second embodiment of the present invention.

In the following, the same reference numbers are assigned to the same or the corresponding elements as those described above.

In the electrode pattern shown in FIG. 3, each electrode includes portions projecting outward for gathering leaked electrode materials, which are formed at positions other than ends of electrodes in contact with the channel regions.

Because of the projecting portions, it is possible to limit the electrode materials gathering at ends of electrodes in contact with the channel regions. Hence, even when the amount of the discharged ink fluctuates, an electrical short circuit does not occur, and the desired electrode pattern can be formed.

The discharged excessive electrode materials are gathered at the projecting portions. Even if the electrode materials leak from the projecting portions, the leaked electrode materials does not influence the characteristics of the transistor at all. Consequently, it is possible to obtain a stable channel width and a stable channel length, and this prevents fluctuations of the characteristics of the transistor. In addition, the length of the drain electrode becomes equal to the channel width, and this allows maximum utilization of the electrode length. Further, since the length of the drain electrode can be increased, in doing so, the channel width also increases, and a large drain current is obtainable.

Next, a method of fabricating the transistor of the present embodiment is explained also with reference to FIG. 5.

As shown in FIG. 5, on the glass substrate 5, for example, the gate electrode 3 is formed from Al or Cr by vacuum deposition, and polyimide is applied on the gate electrode 3 to form the insulating film 6.

Then ultraviolet rays are irradiated on the polyimide insulating film 6 by using a photo mask to form the projecting patterns as shown in FIG. 3. Due to this treatment, the surface of the projecting patterns is activated. On the thus treated surface of the projecting patterns, for example, the source electrode 1 and the drain electrode 2 are formed by printing PEDOT/PSS (polyethylenedioxythiophene / polystyrene sulfonate) by means of inkjet printing or dispenser printing. Then, an organic semiconductor material is applied by spin-coating to form the organic semiconductor layer 4.

By the above process, a transistor as shown in FIG. 5 is formed, which has a stacked structure including the glass substrate 5, the aluminum gate electrode 3, the polyimide insulating film 6, the source electrode 1 and the drain electrode 2 formed from PEDOT/PSS, and the organic semiconductor layer 4.

Below, the characteristics of the thus fabricated transistor are described.

FIG. 8 shows static characteristics of the transistor of the present embodiment, in which the electrodes have projecting portions.

In FIG. 8, the abscissa represents the gate voltage Vg, and the ordinate represents the drain current-Id.

The Vg-Id characteristics of the transistor as shown in FIG. 8 are described below.

In the ON state (namely, an operational state), the drain current-Id=1.6×10⁻⁶ A. (Specifically, in the ON state, Vg=−20 V.)

In the OFF state (namely, non-operational state), the drain current-Id=3.2×10⁻¹⁰ A. (in the OFF state, Vg=0 V.)

Thus, the ratio of the drain current-Id when Vg=−20 V over the drain current-Id when Vg=0 V (below, referred to as “ON/OFF ratio”) is 5.3×10³.

This implies that an electrical short circuit does not occur between the source electrode and the drain electrode, and good transistor characteristics are obtained. Further, since the channel width is increased, a large drain current is obtained.

### Third Embodiment

In this embodiment, the organic semiconductor layer 4 is formed from a non-orientation polymer material having a triallyl amine structure.

In the following, the same reference numbers are assigned to the same or the corresponding elements as those described above.

As shown in FIG. 5, on the glass substrate 5, for example, an Al film is formed by vacuum deposition, and the select line and the gate electrode 3 are formed by photolithography and etching processes. Then, polyimide is applied on the gate electrode 3 to a thickness of 500 nm acting as the insulating film 6 and the interlayer insulating film of the select line and the data line.

Then, exposure of ultraviolet rays is performed on the polyimide insulating film 6 by using a photo mask to form the electrode patterns. Due to this treatment, the surface of the patterns is activated. On the thus treated surface of the patterns, for example, a PEDOT/PSS film is formed by inkjet printing to form the source electrode 1 and the drain electrode 2, and the data line.

Then, an organic semiconductor material, such as a nonorientation polymer material having a triallyl amine structure, is discharged by inkjet printing to form the organic semiconductor layer 4.

Then, a poly-para-xylylene film serving as a passivation layer is deposited on the organic semiconductor layer 4 by chemical vapor deposition to a thickness of 2000 nm.

By the above process, an organic thin film transistor backplane as shown in FIG. 5 is formed.

Further, an ITO (Indium Tin Oxide) film is formed by sputtering to a thickness of 100 nm on another substrate , and further an oriented film is formed by spin coating to a thickness of 200 nm. After orientation treatment, the other substrate and the organic thin film transistor backplane are bonded with silica spacers, and then a liquid crystal material is poured and sealed in the gap between the two substrates, thus forming a liquid crystal panel.

In addition to the liquid crystal panel, other kinds of display panels may also be formed with the substrate of the present embodiment.

For example, after the ITO film is formed on the other substrate, the other substrate and the organic thin film transistor backplane are bonded with silica spacers, and then, an electrophoresis material is poured and sealed in the gap between the two substrates, thus forming an electrophoresis display panel.

Further, if organic EL (electroluminescence) devices are formed to serve as display pixels, and an air shield layer is provided, it is possible to form an organic EL display panel.

Below, specific examples of the present invention are explained. Nevertheless, it should be noted that the present invention is not limited to these examples.

### Example 1

Referring to FIG. 5 again, on a glass substrate 5 an Al film is deposited by vacuum deposition using a shadow mask to a thickness of 50 nm to serve as the gate electrode 3.

Then, polyimide is applied on the gate electrode 3 by spin-coating to a thickness of 250 nm and is baked to 280° C., thus forming the polyimide insulating film 6.

Then, an ultraviolet lamp (having a dose of 10 J/cm²) is used to irradiate the polyimide insulating film 6 by using a photo mask to form patterns each having high surface energy. These patterns are used as electrodes each having obtuse-angled corners.

By inkjet printing, Ag ink is discharged onto the patterns having a high surface energy, and is sintered at 280° C., thus forming the source electrode 1 and the drain electrode 2. The interval between the source electrode 1 and the drain electrode 2 is 5 μm.

Next, a film of an organic semiconductor material, such as triallyl amine expressed by the following chemical formula is applied by spin coating, and is dried. The thickness of the organic semiconductor material film is 30 nm.

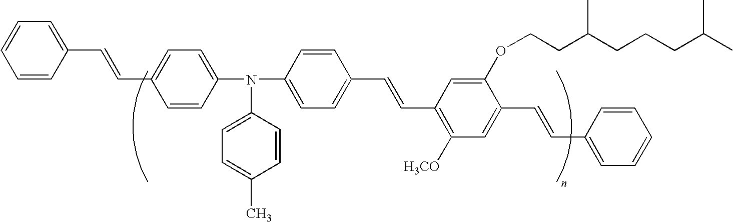

As shown in FIG. 5, the thus fabricated transistor has a stacked structure including the glass substrate 5, the aluminum gate electrode 3, the polyimide insulating film 6 (thickness 250 nm) , the source electrode 1 and the drain electrode 2 formed from Ag, and the organic semiconductor layer 4.

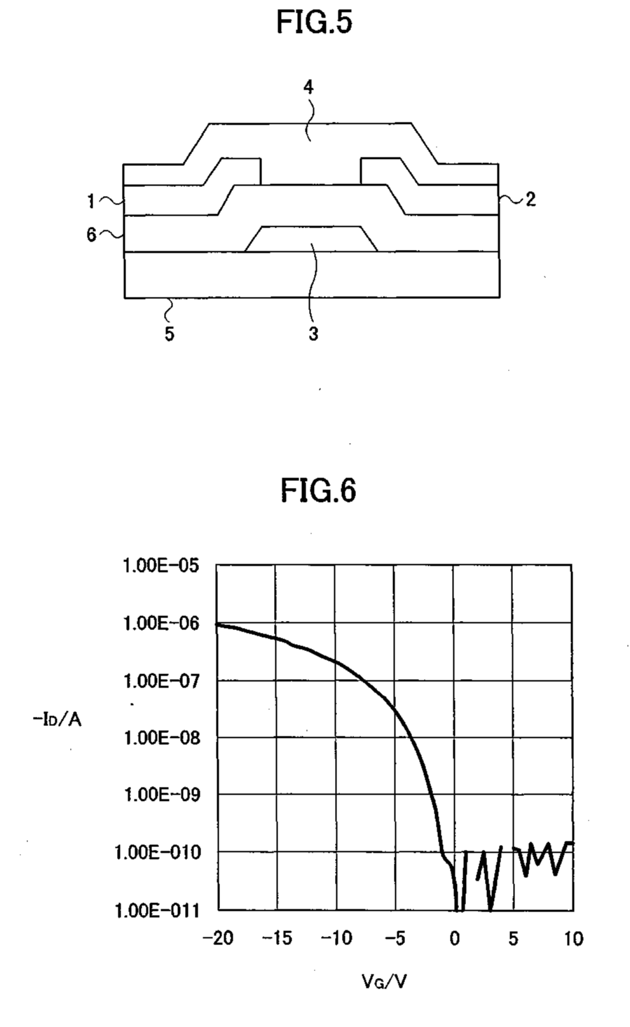

The static characteristics of the thus fabricated transistor are as shown in FIG. 6.

FIG. 6 shows static characteristics of the transistor of the present example, in which the electrodes are formed from Ag ink and have obtuse-angled corners. In FIG. 6, the abscissa represents a gate voltage Vg, and the ordinate represents a drain current-Id.

Specifically, in the ON state (Vg=−20 V), the drain current-Id=0.9×10⁻⁶ A; in the OFF state (Vg=0 V), the drain current-Id =5.0×10⁻¹¹ A. Thus, the ON/OFF ratio (the ratio of the drain current-Id with Vg=−20 V over the drain current-Id with Vg=0 V) is 1.8×10^{4.} This implies that an electrical short circuit does not occur between the source electrode and the drain electrode, and good transistor characteristics are obtained.

### Example 2

Referring to FIG. 5 again, on a glass substrate 5 an Al film is deposited by vacuum deposition using a shadow mask to a thickness of 50 nm to serve as the gate electrode 3.

Then, polyimide is applied on the gate electrode 3 by spin-coating to a thickness of 250 nm and is baked to 280° C., thus forming the polyimide insulating film 6.

Then, an ultraviolet lamp (having a dose of 10 J/cm²) is used to irradiate the polyimide insulating film 6 by using a photo mask to form patterns each having high surface energy. These patterns are used as electrodes each having obtuse-angled corners.

By inkjet printing, a PEDOT/PSS solution is discharged onto the patterns having high surface energy, and is dried at 120° C., thus forming the source electrode 1 and the drain electrode 2. The interval between the source electrode 1 and the drain electrode 2 is 5 μm.

Next, a film of an organic semiconductor material, such as triallyl amine expressed by the above chemical formula is applied by spin coating, and is dried. The thickness of the organic semiconductor material film is 30 nm.

As shown in FIG. 5, the thus fabricated transistor has a stacked structure including the glass substrate 5, the aluminum gate electrode 3, the polyimide insulating film 6 (thickness 250 nm),r the source electrode 1 and the drain electrode 2 formed from PEDOTIPSS, and the organic semiconductor layer 4.

The static characteristics of the thus fabricated transistor are as shown in FIG. 7.

Specifically, in the ON state (Vg=−20 V), the drain current-Id=0.8×10⁻⁶ A; in the OFF state (Vg=0 V), the drain current-Id=2.5×10⁻¹⁰ A. Thus, the ON/OFF ratio (the ratio of the drain current-Id with Vg=−20 V over the drain current-Id with Vg=0 V) is 3.5×10³. This implies that an electrical short circuit does not occur between the source electrode and the drain electrode, and good transistor characteristics are obtained.

### Example 3

In this example, the pattern is formed in a different way from the example 1.

The other steps are the same as the example 1.

When forming the electrode patterns, an ultraviolet lamp (having a dose of 10 J/cm²) is used to irradiate the polyimide insulating film 6 by using a photo mask to form patterns each pattern having high surface energy. These patterns are shaped to have projecting portions.

The thus fabricated transistor has a stacked structure including the glass substrate 5, the aluminum gate electrode 3, the polyimide insulating film 6 (thickness 250 nm), the source electrode 1 and the drain electrode 2 formed from PEDOT/PSS, and the organic semiconductor layer 4.

The static characteristics of the transistor are as shown in FIG. 8.

Specifically, in the ON state (Vg=−20 V), the drain current-Id=1.6×10⁻⁶ A; in the OFF state (Vg=0 V), the drain current-Id=3.2×10⁻¹⁰ A. Thus, the ON/OFF ratio (the ratio of the drain current-Id with Vg=−20 V over the drain current-Id with Vg=0 V) is 5.3×10³. This implies that an electrical short circuit does not occur between the source electrode and the drain electrode, and good transistor characteristics are obtained. In addition, since the electrode length (namely, the channel width) is increased, a large drain current is obtained.

While the present invention is above described with reference to specific embodiments chosen for purpose of illustration, it should be apparent that the invention is not limited to these embodiments, but numerous modifications could be made thereto by those skilled in the art without departing from the basic concept and scope of the invention.

This patent application is based on Japanese Priority Patent Applications No. 2005-146047 filed on May 18, 2005, and No. 2006-103671 filed on Apr. 4, 2006, the entire contents of which are hereby incorporated by reference.

1. An organic thin film transistor, comprising:
a substrate;
a gate electrode;
a gate insulating film
a source electrode on the gate insulating film;
a drain electrode on the gate insulating film at an interval with the source electrode; and
an organic semiconductor layer ;
wherein
the gate insulating film includes an electrode formation region having surface energy modified by energy deposition,
one or more corners of the electrode formation region have an obtuse-angled shape, and
the source electrode and/or the drain electrode is formed in the electrode formation region so as to have substantially the same shape as the electrode formation region having the obtuse-angled shaped corners.

2. An organic thin film transistor, comprising:
a substrate;
a gate electrode;
a gate insulating film
a source electrode on the gate insulating film;
a drain electrode on the gate insulating film at an interval with the source electrode; and
an organic semiconductor layer
wherein
the gate insulating film includes an electrode formation region having surface energy modified by energy deposition,
one or more corners of the electrode formation region have a round shape, and
the source electrode and/or the drain electrode is formed in the electrode formation region so as to have substantially the same shape as the electrode formation region having the round corners.

3. An organic thin film transistor, comprising:
a substrate;
a gate electrode;
a gate insulating film;
a source electrode on the gate insulating film;
a drain electrode on the gate insulating film at an interval with the source electrode; and
an organic semiconductor layer
wherein
the source electrode and the drain electrode are formed on the gate insulating film which gate insulating film has surface energy increased by energy deposition, and
the source electrode and/or the drain electrode has at least one projecting portion.

4. The organic thin film transistor as claimed in claim 3, wherein at least one of the source electrode and the drain electrode has substantially the same shape as a portion of the gate insulating film which portion has an increased surface energy.

5. The organic thin film transistor as claimed in claim 4, wherein the portion of the gate insulating film having the increased surface energy is formed by irradiation of ultraviolet rays.

6. The organic thin film transistor as claimed in claim 1, wherein the gate insulating film is an organic insulating film formed from a polymer material.

7. The organic thin film transistor as claimed in claim 6, wherein the organic insulating film includes a polyimide film.

8. The organic thin film transistor as claimed in claim 1, wherein the gate electrode, the source electrode, and the drain electrode are formed from metal ink obtained by dispersing metal fine particles.

9. The organic thin film transistor as claimed in claim 8, wherein the metal fine particles include at least one of Au, Ag, Cu, and Ni as a main component.

10. The organic thin film transistor as claimed in claim 1, wherein the gate electrode, the source electrode, and the drain electrode are formed from a conductive polymer material.

11. The organic thin film transistor as claimed in claim 10, wherein the conductive polymer material includes polyethylenedioxythiophene.

12. The organic thin film transistor as claimed in claim 1, wherein the source electrode and the drain electrode are formed by inkjet printing or dispenser printing.

13. The organic thin film transistor as claimed in claim ¹, wherein the organic semiconductor layer is formed by inkjet printing or dispenser printing.

14. The organic thin film transistor as claimed in claim 9, wherein the organic semiconductor layer is formed from a polymer material having a triallyl amine structure.

15. An active matrix display device, comprising:
a plurality of pixels, each pixel having an organic thin film transistor as an active device;
wherein
the organic thin film transistor includes
a substrate;
a gate electrode
a gate insulating film
a source electrode on the gate insulating film;
a drain electrode on the gate insulating film at an interval with the source electrode; and
an organic semiconductor layer o;
wherein
the gate insulating film includes an electrode formation region having surface energy modified by energy deposition,
at least one or more corners of the electrode formation region have an obtuse-angled shape, and
the source electrode and/or the drain electrode is formed in the electrode formation region so as to have substantially the same shape as the electrode formation region which electrode formation region has the obtuse-angled shaped corners.
